(19) United States
(12) Patent Application Publication
(10) Pub. No.: US 2009/0020883 A1
(43) Pub. Date: Jan. 22, 2009

(54) SEMICONDUCTOR DEVICE AND METHOD FOR FABRICATING SEMICONDUCTOR DEVICE

(76) Inventors: Kayo Nomura, Kanagawa (JP); Junichi Wada, Kanagawa (JP); Hideto Matsuyama, Kanagawa (JP); Masayuki Kitamura, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/175,132

(22) Filed: Jul. 17, 2008

(30) Foreign Application Priority Data
Jul. 20, 2007 (JP) 2007-189197

(51) Int. Cl. H01L 23/48; H01L 21/44

(52) U.S. Cl. 257/774; 438/637; 257/E23.01; 257/E21.476

(57) ABSTRACT

A semiconductor device includes a first contact plug arranged above a semiconductor substrate and using aluminum (Al) as a material; a second contact plug arranged on and in contact with the first contact plug and using a refractory metal material; a first dielectric film arranged on a flank side of the first and second contact plugs; a wire arranged above the second contact plug and using copper (Cu) as a material; a second dielectric film arranged on a flank side of the wire; and a barrier film arranged at least between the wire and the first dielectric film and between the wire and the second dielectric film.

### CROSS-REFERENCE TO RELATED APPLICATION

This application is based upon and claims the benefit of priority from prior Japanese Patent Application No. 2007-189197 filed on Jul. 20, 2007 in Japan, the entire contents of which are incorporated herein by reference.

### BACKGROUND OF THE INVENTION

1. Field of the Invention

The invention relates to a semiconductor device and a method for fabricating a semiconductor device, and for example, relates to a semiconductor device in which a contact plug for connecting a device portion and a copper (Cu) wire is arranged and a manufacturing method thereof.

2. Description of the Related Art

In recent years, with ever higher degrees of integration and higher performance of semiconductor integrated circuits (LSI), new microprocessing technologies have been developed. In particular, to achieve an ever faster speed of LSI, there has been a growing trend recently to replace the conventional wire material of aluminum (Al) alloys with copper (Cu) or Cu alloys (hereinafter, called Cu together) having lower resistance. Since it is difficult to apply the dry etching method, which is frequently used for forming an Al alloy wire, to Cu for microprocessing, the so-called damascene process is mainly adopted for Cu, in which a Cu film is deposited onto a dielectric film to which groove processing has been provided and then the Cu film is removed except in portions where the Cu film is embedded inside a groove by chemical-mechanical polishing (CMP) to form an embedded wire.

A low dielectric constant material film (low-k film) having a low relative dielectric constant is used as an inter-level dielectric in a wiring layer. That is, an attempt is made to reduce parasitic capacitance between wires by using a low dielectric constant material film (low-k film) whose relative dielectric constant k is 3 or less, instead of a silicon oxide film (SiO₂) whose relative dielectric constant k is about 4.2. To prevent diffusion of Cu into the low-k film, a barrier metal film of titanium nitride (TiN) or the like is first formed on the wall surface and at the bottom of a groove and then Cu is embedded.

Here, with increasingly finer patterns of LSI in recent years as described above, the diameter of a contact hole for connecting a Cu wire and a substrate diffusion layer and that of a contact hole for connecting a Cu wire and a transistor's gate electrode are becoming smaller, making the aspect ratio of the contact hole higher. Thus, an increase in contact resistance in a contact plug is becoming increasingly serious. If a commonly used plug of tungsten (W) can be changed to Al having lower resistance, lower resistance becomes realizable so that an increase in contact resistance can be avoided. However, if Al is used as the material of plug electrically connecting a device portion such as a substrate diffusion layer and gate electrode and a Cu wire, Cu to be a wire will cause an alloy reaction with Al with the thickness of a barrier metal film of a conventionally used wiring layer. Thus, a problem that a new source of high resistance is created arises. While it is possible to make the above barrier metal film thicker to prevent the alloy reaction between Al and Cu, making the barrier metal film thicker in turn causes a problem that the wire itself will have higher resistance.

Here, though not a contact plug for connecting a device portion and a wire, an example in which an Al plug is used as a via plug for connecting Cu wires in upper-lower layers in a multiplayer interconnection structure to reduce resistance in the multiplayer interconnection structure is disclosed (See Japanese Unexamined Patent Application Publication No. 2006-216690). Also in this example, though, the Al plug is connected to the Cu wires in upper-lower layers directly or via the barrier metal film and therefore, it is difficult to adequately prevent higher resistance based on the alloy reaction between Al and Cu.

### BRIEF SUMMARY OF THE INVENTION

A semiconductor device in an aspect of the invention, includes a first contact plug arranged above a semiconductor substrate and using aluminum (Al) as a material; a second contact plug arranged on and in contact with the first contact plug and using a refractory metal material; a first dielectric film arranged on a flank side of the first and second contact plugs; a wire arranged above the second contact plug and using copper (Cu) as a material; a second dielectric film arranged on a flank side of the wire; and a barrier film arranged at least between the wire and the first dielectric film and between the wire and the second dielectric film.

A method for fabricating a semiconductor device in another aspect of the invention, includes forming a first dielectric film above a semiconductor substrate; forming a first opening in the first dielectric film; causing an aluminum (Al) film to deposit so that the first opening is filled up; etching an upper part of the Al film filled up in the first opening; causing a refractory metal material film to deposit inside the first opening formed by the upper part of the Al film being etched; and forming a wire using copper (Cu) as a material above the refractory metal material film.

A method for fabricating a semiconductor device in another aspect of the invention, includes forming a first dielectric film above a semiconductor substrate; forming a first opening in the first dielectric film; causing an aluminum (Al) film to deposit so that the first opening is filled up; etching an upper part of the Al film filled up in the first opening; causing a refractory metal material film to deposit inside the first opening formed by the upper part of the Al film being etched; forming a second dielectric film above the first dielectric film and the refractory metal material film; forming a second opening reaching the refractory metal material film in the second dielectric film; forming a seed film using copper (Cu) containing manganese (Mn) as a material inside the second opening; filling the second opening with Cu using the seed film as a cathode electrode; and forming a barrier film containing Mn, silicon (Si), and oxygen (O) from the seed film.

### BRIEF DESCRIPTION OF THE DRAWINGS

FIG. 1 is a flow chart showing principal parts of a manufacturing method of a semiconductor device according to a first embodiment.

FIG. 2A to FIG. 2D are process cross sections showing processes performed corresponding to the flow chart in FIG. 1.

FIG. 3A to FIG. 3D are process cross sections showing processes performed corresponding to the flow chart in FIG. 1.

FIG. 4A to FIG. 4C are process cross sections showing processes performed corresponding to the flow chart in FIG. 1.

FIG. 5A to FIG. 5C are process cross sections showing processes performed corresponding to the flow chart in FIG. 1.

FIG. 6 is a process cross section showing a process performed corresponding to the flow chart in FIG. 1.

FIG. 7 is a diagram showing a result of an experiment to measure plug resistance when the type of a refractory metal plug in the first embodiment is changed.

FIG. 8 is a flow chart showing principal parts of a manufacturing method of a semiconductor device according to a second embodiment.

FIG. 9A to FIG. 9C are process cross sections showing processes performed corresponding to the flow chart in FIG. 8.

### DETAILED DESCRIPTION OF THE INVENTION

In embodiments shown below, semiconductor devices that make resistance of a contact plug lower than before while preventing an alloy reaction between Al and Cu and a manufacturing method thereof will be described.

### First Embodiment

In the first embodiment, a configuration in which a barrier layer is placed between a refractory metal plug and a Cu wire provided above an Al plug will be described. The first embodiment will be described below with reference to drawings.

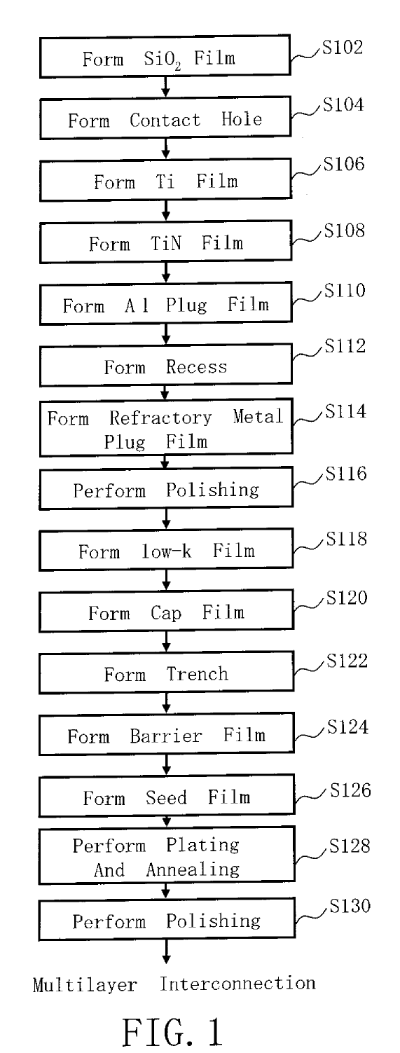

FIG. 1 is a flow chart showing principal parts of a manufacturing method of a semiconductor device according to the first embodiment. In FIG. 1, a series of processes including an SiO₂ film formation process (S102), a contact hole formation process (S104), a titanium (Ti) film formation process (S106), a titanium nitride (TiN) film formation process (S108), an Al plug film formation process (S110), a recess formation process (S112), a refractory metal plug film formation process (S114), a polishing process (S116), a low-k film formation process (S118), a cap film formation process (S120), a trench formation process (S122), a barrier film formation process (S124), a seed film formation process (S126), a plating and annealing process (S128), and a polishing process (S130) is performed by the manufacturing method of a semiconductor device according to the first embodiment.

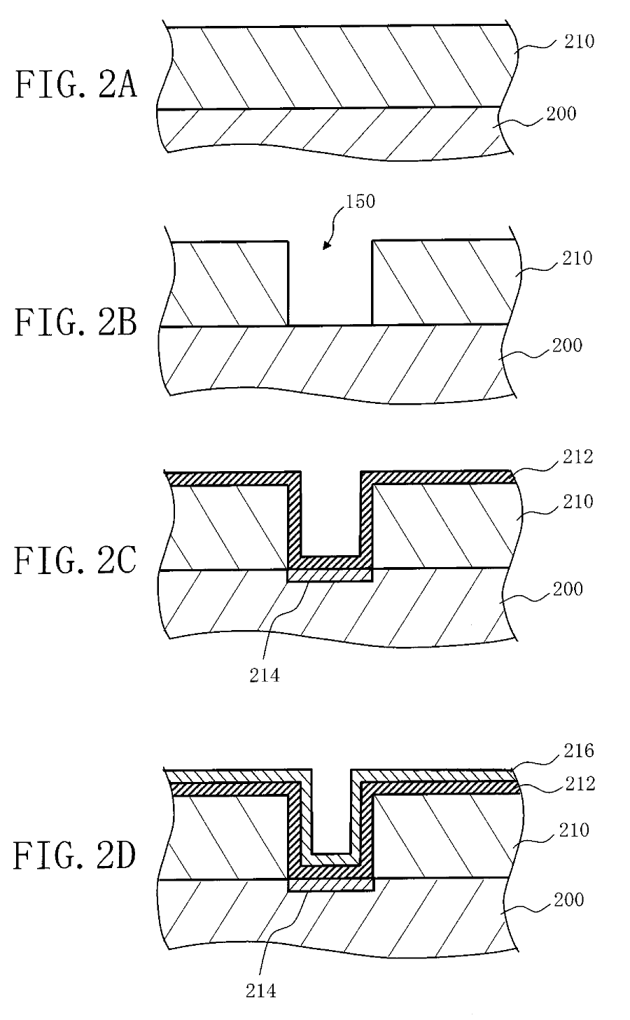

FIG. 2A to FIG. 2D are process cross sections showing processes performed corresponding to the flow chart in FIG. 1. FIG. 2A to FIG. 2D show the SiO₂ film formation process (S102) to the TiN film formation process (S108) in FIG. 1.

In FIG. 2A, as the SiO₂ film formation process (S102), SiO₂ is deposited onto the surface of a substrate 200 where a device portion such as a substrate diffusion layer and a gate electrode is formed by the CVD (chemical vapor deposition) method to form an SiO₂ film 210 to be a dielectric film of the thickness of, for example, 300 nm. Here, though the film is formed by the CVD method, other methods may also be used. As the substrate 200, a silicon wafer of, for example, 300 mm in diameter is used. An illustration of the device portion is here omitted.

In FIG. 2B, as the contact hole formation process (S104), an opening 150 to be a contact hole structure for connecting to the device portion in lithography and dry etching processes is formed inside the SiO₂ film 210. The opening 150 can be formed substantially perpendicularly to the surface of the substrate 200 by removing the exposed SiO₂ film 210 by the anisotropic etching method with respect to the substrate 200 where a resist film is formed on the SiO₂ film 210 by undergoing the lithography process such as a resist application process and an exposure process (not shown). For example, the opening 150 may be formed by the reactive ion etching method.

In FIG. 2C, as the Ti film formation process (S106), a Ti film 212 using Ti is formed on inner walls (on sidewalls and at the bottom) of the opening 150 formed by the opening formation process and on the surface of the SiO₂ film 210. The Ti film 212 is formed by depositing a thin film of Ti in a sputtering device using a sputter process, which is a kind of the PVD (physical vapor deposition) method, for example, to a thickness of 20 nm under substrate temperature conditions of 200° C. The deposition method of Ti is not limited to the PVD method and the CVD method may also be used. Particularly when the plasma CVD method is used to provide directivity, the Ti film 212 can be formed thinner on the sidewalls than that formed at the bottom of the opening 150 with the thickness of 20 nm. Accordingly, an increase in plug resistance can be controlled. Then, the Ti film 212 formed at the bottom of the opening 150 to be an adhesion layer reduces and eliminates an oxide film of the substrate 200 formed at the bottom of the opening 150 to form a titanium silicide (TiSi₂) film 214. Accordingly, an ohmic contact can be secured.

In FIG. 2D, as the TiN film formation process (S108), a TIN film 216 to be a barrier metal film is caused to deposit (form) on the inner walls (on the sidewalls and at the bottom) of the opening 150 and on the surface of the substrate 200 where the Ti film 212 is formed by the PVD method such as sputtering, for example, to a thickness of 5 nm under substrate temperature conditions of 400° C. By forming the TiN film 216, reactions between silicon in the semiconductor substrate 200 and a plug metal and between silicon contained in the SiO₂ film 210 to be an inter-level dielectric and the plug metal, and diffusion of the plug metal can be prevented.

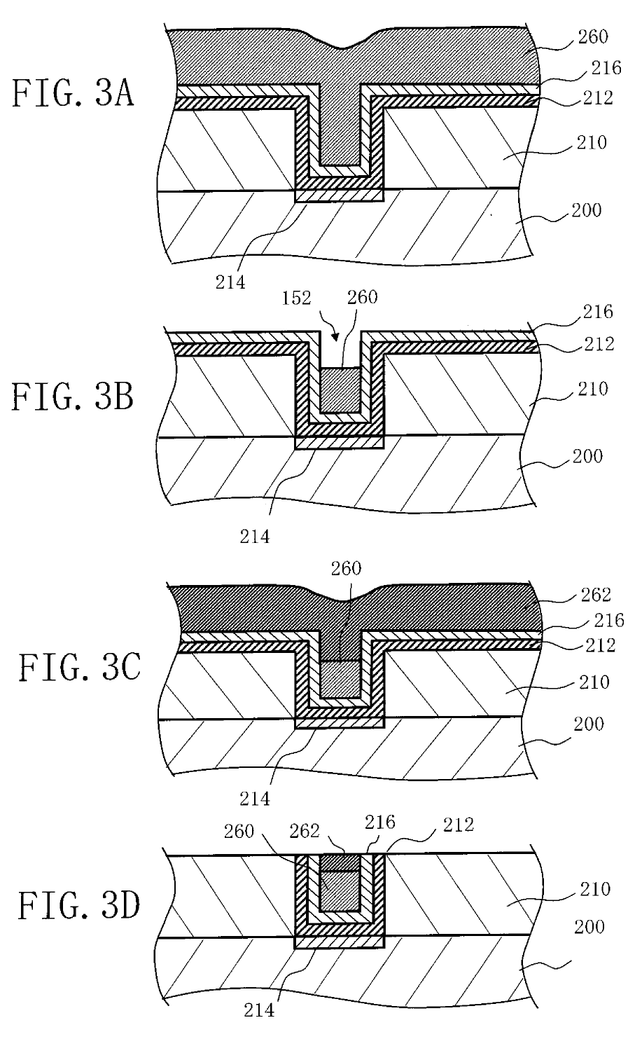

FIG. 3A to FIG. 3D are process cross sections showing processes performed corresponding to the flow chart in FIG. 1. FIG. 3A to FIG. 3D show the Al plug film formation process (S110) to the polishing process (S116) in FIG. 1.

In FIG. 3A, as the Al plug film formation process (S110), an Al film 260 to be a first-stage contact plug is caused to deposit (form) inside the opening 150 and on the surface of the substrate 200 where the Ti film 212 and the TiN film 216 are formed by the PVD method such as sputtering to a thickness of, for example, 500 nm so that the whole opening 150 is filled up. The deposition method of Al is not limited to the PVD method and the CVD method may also be used.

In FIG. 3B, as the recess formation process (S112), an upper part of the Al film 260 filled up in the opening 150 is etched to form a recess 152. Here, the Al film 260 can be selectively etched to leave the TiN film 216 below. The recess 152 preferably has a depth of 15 to 50 nm. The anisotropic etching method is suitably applied to remove the Al film 260. Accordingly, the recess 152 can be formed substantially perpendicularly to the surface of the substrate 200. For example, the recess 152 may be formed by the reactive ion etching method. A chlorine based gas may be used as an etching gas. For example, BCl₃ or Cl₂ is suitably used.

In FIG. 3C, as the refractory metal plug film formation process (S114), a refractory metal material film is caused to deposit inside the recess 152 formed by etching the upper part of the Al film 260. A refractory metal film 262 to be a second-stage contact plug is caused to deposit (form) inside the recess 152 and on the surface of the substrate 200 by the CVD method to a thickness of, for example, 500 nm so that the whole recess 152 is filled up. The deposition method of the refractory metal film 262 is not limited to the CVD method and the PVD method may also be used. At least one of tungsten (W), tungsten nitride (WN), Ti, TiN, tantalum (Ta), tantalum nitride (TaN), and cobalt (Co) can be used as a material of the refractory metal film 262. It is desirable that the foundation layer be a metal film when the refractory metal film 262 such as the above metals is caused to deposit. Here, however, when the recess 152 described above is formed, etching is performed so that the TiN film 216 is left to eliminate the need to newly form a metal film and therefore, the TiN film 216 can be used as it is. Thus, the number of processes can be reduced therefor.

In FIG. 3D, as the polishing process (S116), the surface of the substrate 200 is polished by the CMP method to remove by polishing the refractory metal film 262, the TiN film 216, and the Ti film 212 deposited on the surface excluding the opening. As a result, planarization as shown in FIG. 3D can be accomplished.

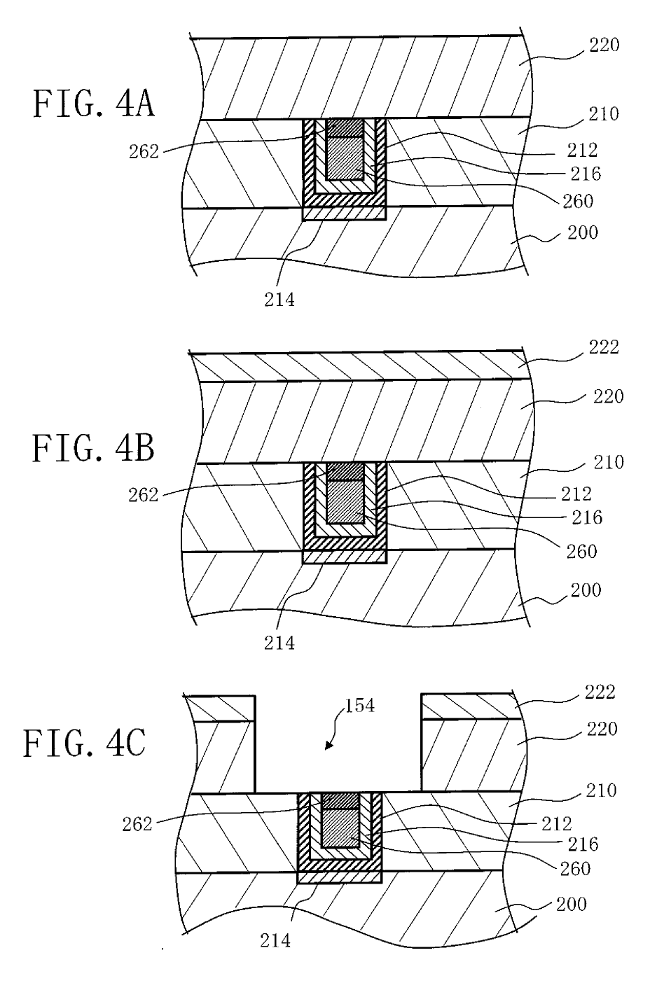

FIG. 4A to FIG. 4C are process cross sections showing processes performed corresponding to the flow chart in FIG. 1. FIG. 4A to FIG. 4C show the low-k film formation process (S118) to the trench formation process (S122).

In FIG. 4A, as the low-k film formation process (S118), a dielectric film 220 using a porous and low dielectric constant dielectric material is formed on the substrate 200 in which a contact plug in a two-stage structure of the Al film 260 and the refractory metal film 262 to a thickness of, for example, 100 nm. Porous silicon oxycarbide (SiOC) is suitably used as the material of the dielectric film 220. An inter-level dielectric whose relative dielectric constant k is about 2.5 can be obtained from a porous SiOC film. Here, the dielectric film 220 is formed, as an example, using material whose main component is methylsiloxane. In addition to polymethylsiloxane whose main component is methylsiloxane, a film having siloxane backbone structures such as polysiloxane, hydrogen silsesquioxane, and methylsilsesquioxane may be used as materials of the dielectric film 220. The SOD (spin on dielectric coating) method by which a thin film is formed by spin-coating and heat-treating a solution may be used as a formation method. The dielectric film 220 is formed, for example, by forming a film by a spinner, baking the substrate on a hot plate in a nitrogen atmosphere, and then curing the substrate at temperature higher than that during baking on the hot plate in the nitrogen atmosphere. In addition to the SOD method, the CVD method may be used as the formation method.

In FIG. 4B, as the cap film formation process (S120), a cap dielectric film 222 is formed by depositing SiOC onto the dielectric film 220 by the CVD method to a thickness of, for example, 20 nm. In addition to SiOC whose relative dielectric constant k is about 3.0, for example, SiO₂ whose relative dielectric constant k is about 4.0 can be used as the cap dielectric film 222. By forming the cap dielectric film 222, the dielectric film 220 of SiOC whose mechanical strength is weak can be protected.

In FIG. 4C, as the trench formation process (S122), an opening 154, which is a trench structure for making a damascene wire in the lithography and dry etching processes is formed inside the SiOC film 222 and the dielectric film 220. The opening 154 is formed on the contact plug in the two-stage structure of the Al film 260 and the refractory metal film 262. The opening 154 can be formed substantially perpendicularly to the surface of the substrate 200 by removing the exposed SiOC film 222 and the dielectric film 220 by the anisotropic etching method with respect to the substrate 200 where a resist film is formed on the SiOC film 222 by undergoing the lithography process such as the resist application process and exposure process (not shown). For example, the opening 154 may be formed by the reactive ion etching method.

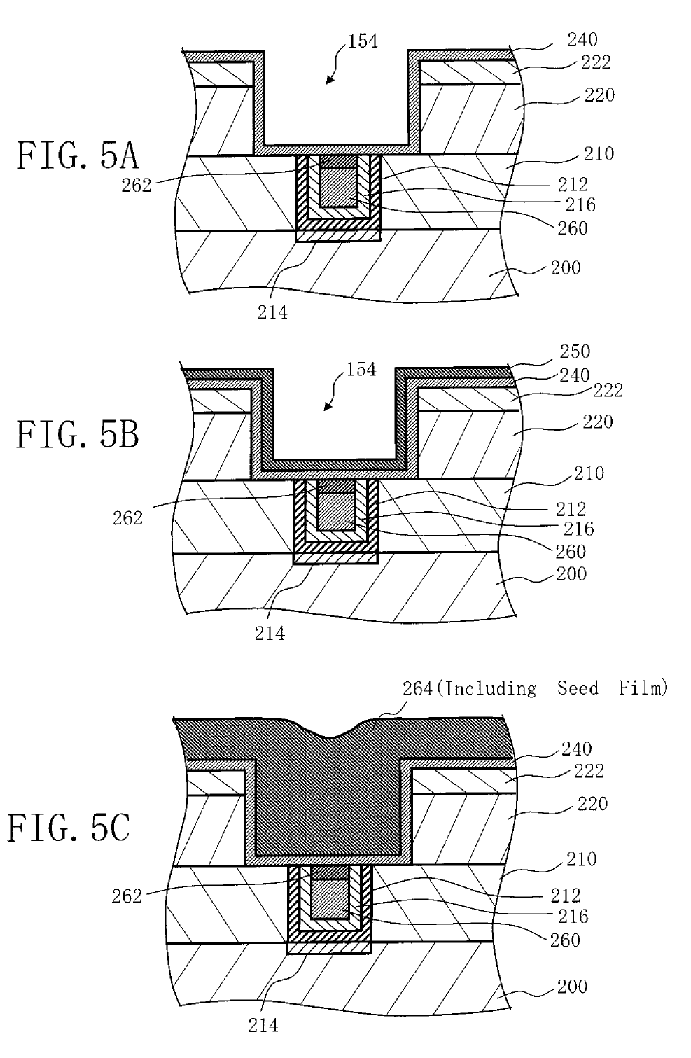

FIG. 5A to FIG. 5C are process cross sections showing processes performed corresponding to the flow chart in FIG. 1. FIG. 5A to FIG. 5C show the barrier film formation process (S124) to the plating and annealing process (S128).

In FIG. 5A, as the barrier film formation process (S124), a barrier metal film 240 using barrier metal material is formed here inside the opening 154 formed by the opening formation process and on the surface of the SiOC film 222. For example, a thin film of Ta film is deposited to a thickness of, for example, 5 nm in a sputtering device using the sputter process to form the barrier metal film 240. The deposition method of a barrier metal material is not limited to the PVD method and other methods such as the atomic layer deposition (ALD) method (or the atomic layer chemical vapor deposition (ALCVD) method) or the CVD method may also be used. The coverage factor can be made better than when the PVD method is used. In addition to Ta, tantalum nitride (TaN), titanium (Ti), tungsten (W), titanium nitride (TiN), tungsten nitride (WN), or laminated films combining these such as Ta and TaN as the material of the barrier metal film.

In FIG. 5B, as the seed film formation process (S126), a Cu thin film to be a cathode electrode in the next electro-plating process is caused to deposit (form) on the inner walls of the opening 154 and on the surface of the substrate 200 where the barrier metal film 240 is formed as a seed film 250.

In FIG. 5C, as the plating and annealing process (S128), a Cu film 264 is caused to deposit in the opening 154 and on the surface of the substrate 200 by an electrochemical deposition method such as electro-plating using the seed film 250 as a cathode electrode. Here, for example, the Cu film 264 of 200 nm in thickness is caused to deposit and after the deposition, annealing is performed at, for example, 250° C. for 30 min.

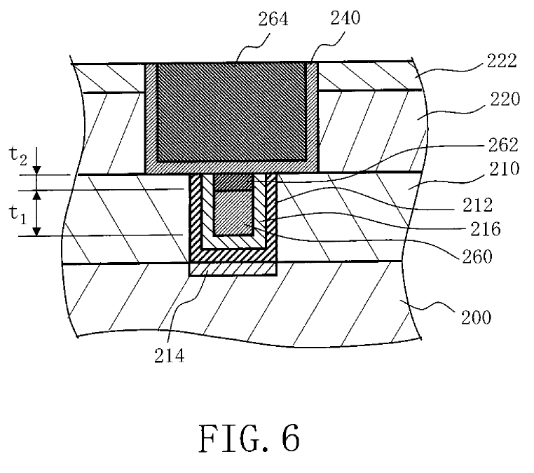

FIG. 6 is a process cross section showing a process performed corresponding to the flow chart in FIG. 1. FIG. 6 shows the polishing process (S130) in FIG. 1.

In FIG. 6, as the polishing process (S130), the excessive Cu film 264 and the barrier metal film 240 deposited out of the opening 154 are polished and removed by CMP. As a result, planarization as shown in FIG. 6 can be accomplished. By forming a damascene wire in this manner, a Cu wiring layer to be a local wiring layer is formed. For example, a Cu wire with the minimum wire width of 65 nm can be formed. Then, for example, a wiring layer whose minimum wiring rule of line and space is 65 nm/65 nm and whose wiring height is 120 nm can be formed.

As described above, the semiconductor device has the Al film 260 to be the first-stage contact plug above a substrate where a device portion is formed and the refractory metal film 262 to be the second-stage contact plug arranged on and in contact with the Al film 260 and using a refractory metal material. Then, a Cu wire indicated by the Cu film 264 is arranged above the refractory metal film 262. The SiO₂ film 210 to be the first dielectric film is arranged on the flank side of the Al film 260 and the refractory metal film 262, and laminated films of the dielectric film 220 and the cap dielectric film 222 to be the second dielectric film are arranged on the flank side of the Cu film 264. At least the barrier metal film 240 to be a barrier film is arranged between the Cu film 264 and the SiO₂ film 210 and between the Cu film 264 and the dielectric film 220. In the first embodiment, a configuration in which the barrier metal film 240 is formed also between the Cu film 264 and the refractory metal film 262 is described. However, it is difficult to control an alloy reaction between the Cu film 264 and the Al film 260 with the thickness of the barrier metal 240 and the alloy reaction can be controlled by placing the refractory metal film 262 in between. It is also desirable from the viewpoint of making resistance lower that the Al film 260 be formed to a thickness t1, which is thicker than a thickness t2 of the refractory metal film 262.

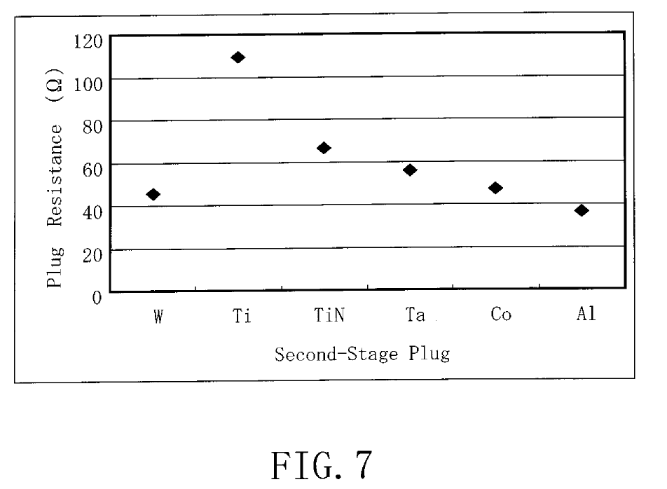

FIG. 7 is a diagram showing a result of an experiment to measure plug resistance when the type of the refractory metal plug in the first embodiment is changed. Here, the first-stage Al film 260 (Al plug) is caused to deposit to the thickness t1 of 250 nm and the second-stage refractory metal film 262 to the thickness t2 of 50 nm in the opening 150 (contact hole) with the diameter of 70 nm and the depth of 300 nm. If the opening 150 is configured by a conventional W plug only, the W plug resistance will be 140 Ω. In contrast, as shown in FIG. 7, the experiment showed that plug resistance of all materials falls below the W plug resistance (140 Ω) if the thickness t2 of the refractory metal film 262 is at least up to 50 nm. Though not shown here for WN and TaN, a similar result is obtained. While barrier properties of each refractory metal material to control an alloy reaction between Cu and Al cannot be generalized, it is evident from experimental data that barrier properties can be secured for all refractory metal materials if the thickness thereof is 15 nm or more. Thus, the thickness t2 of the refractory metal film 262 is suitably made 15 nm or more. By adopting the above configuration, resistance of a contact plug can be made lower while preventing an alloy reaction between Al and Cu.

### Second Embodiment

In the first embodiment, a configuration in which the barrier metal film 240 is formed also between the Cu film 264 and the refractory metal film 262 is described. However, the invention is not limited to this. In the second embodiment, a case in which the Cu film 264 and the refractory metal film 262 come into contact will be described. The second embodiment will be described below with reference to drawings.

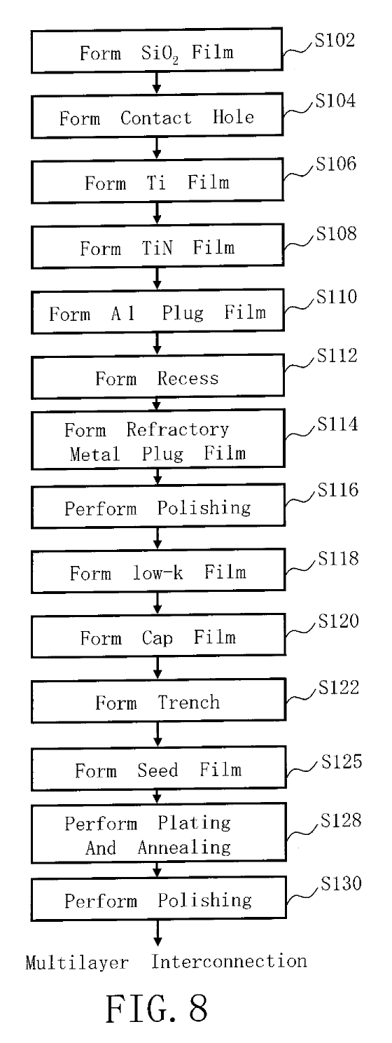

FIG. 8 is a flow chart showing principal parts of a manufacturing method of a semiconductor device according to the second embodiment. In FIG. 8, the manufacturing method of a semiconductor device in the second embodiment is the same as in FIG. 1 except that the barrier film formation process (S124) is deleted and, instead of the seed film formation process (S126), a seed film formation process (S125) is provided. Thus, each process from the SiO₂ film formation process (S102) to the trench formation process (S122) is the same as each corresponding process in the first embodiment. Therefore, the cross section structure shown in FIG. 4C and thereafter will be described.

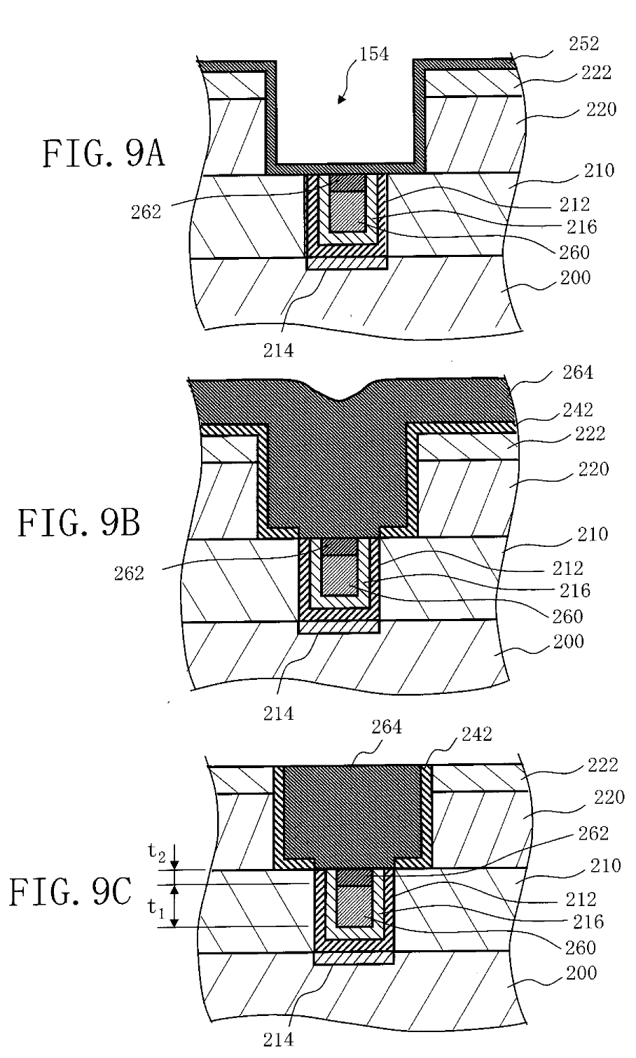

FIG. 9A to FIG. 9C are process cross sections showing processes performed corresponding to the flow chart in FIG. 8. FIG. 9A to FIG. 9C show the seed film formation process (S125) to the polishing process (S130) in FIG. 8.

In FIG. 9A, as the seed film formation process (S125), a seed film 252 to be a cathode electrode in the next electro-plating process is caused to deposit (form) on the inner walls (at the bottom and on the wall surface) of the opening 154 and on the surface of the SiOC film 222 by the PVD method such as sputtering from the state shown in FIG. 4C. Here, a Cu seed film containing manganese (Mn) is used as the seed film 252.

In FIG. 9B, as the plating and annealing process (S128), the Cu film 264 to be a conductive material is caused to deposit inside the opening 154 and on the surface of the substrate 200 by the electrochemical deposition method based on electro-plating using the seed film 252 as a cathode electrode. Here, for example, the Cu film 264 of 200 nm in thickness is caused to deposit and after the deposition, annealing is performed at, for example, 250° C. for 30 min. By performing annealing, Mn in the seed film 252 is diffused to sidewalls of the dielectric film to form MnSixOy at an interface with the dielectric film after Mn being bound to silicon (Si) and oxygen (O). Silicon and oxygen can be fed from the SiO₂ film 210, the dielectric film 220 and the SiOC film 222. MnSixOy self-formed in this manner will become a barrier film 242. Thus, in the second embodiment, the barrier film formation process before the seed film formation process can be omitted. Moreover, MnSixOy is not formed at an interface on the refractory metal film 262 of the seed film 252 deposited on the inner walls of the opening 154 not in contact with the SiO₂ film 210. Thus, the refractory metal film 262 will directly be in contact with the Cu film 264.

In FIG. 9C, as the polishing process (S130), the excessive Cu film 264 and the barrier film 242 disposed out of the opening 154 are polished and removed by CMP. As a result, planarization as shown in FIG. 9C can be accomplished. By forming a damascene wire in this manner, a Cu wiring layer to be a local wiring layer is formed. For example, a Cu wire with the minimum wire width of 65 nm can be formed. Then, for example, a wiring layer whose minimum wiring rule of line and space is 65 nm/65 nm and whose wiring height is 120 nm can be formed.

Even if the refractory metal film 262 is directly in contact with the Cu film 264, as described above, resistance of a contact plug can be made lower while preventing an alloy reaction between Al and Cu.

According to each embodiment, as described above, Al can be used as the material of a contact plug. As a result, resistance of the contact plug can be made lower.

In the above description, a similar effect can be produced by using, other than Cu, materials containing Cu used in the semiconductor industry as a main component such as a Cu—Sn alloy, a Cu—Ti alloy, and a Cu—Al alloy as a material of wiring layers in each of the above embodiments.

Embodiments of the invention have been described above with reference to concrete examples. However, the invention is not limited to these concrete examples.

Further, the thickness of inter-level dielectric, the size, shape, and number of openings and the like may be used by selecting what is needed for semiconductor integrated circuits and various semiconductor devices as needed.

In addition, all semiconductor devices and manufacturing methods of semiconductor devices having elements of the invention and whose design can be modified as needed by those skilled in the art are included in the scope of the invention.

Though techniques normally used in the semiconductor industry, for example, a photolithography process and cleaning before and after treatment are omitted for simplification of the description, such techniques are naturally included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a first contact plug arranged above a semiconductor substrate and using aluminum (Al) as a material;
a second contact plug arranged on and in contact with the first contact plug and using a refractory metal material;
a first dielectric film arranged on a flank side of the first and second contact plugs;
a wire arranged above the second contact plug and using copper (Cu) as a material;
a second dielectric film arranged on a flank side of the wire; and
a barrier film arranged at least between the wire and the first dielectric film and between the wire and the second dielectric film.

2. The device according to claim 1, wherein the first contact plug is formed to a thickness thicker than that of the second contact plug.

3. The device according to claim 1, wherein the wire is arranged over the second contact plug via the barrier film.

4. The device according to claim 1, wherein the second contact plug and the wire are arranged by being in contact with each other.

5. The device according to claim 4, wherein the barrier film contains manganese (Mn), silicon (Si), and oxygen (O).

6. The device according to claim 5, wherein the barrier film is not formed on the second contact plug and is self-formed between the wire and the first dielectric film and between the wire and the second dielectric film.

7. The device according to claim 1, wherein at least one of tungsten (W), tungsten nitride (WN), titanium (Ti), titanium nitride (TiN), tantalum (Ta), tantalum nitride (TaN), and cobalt (Co) is used as the refractory metal material.

8. The device according to claim 1, wherein the first dielectric film is arranged on the flank side of the first and second contact plugs via a barrier metal film.

9. The device according to claim 8, wherein the first contact plug is arranged over the semiconductor substrate via the barrier metal film.

10. The device according to claim 9, wherein the barrier metal film contains titanium nitride (TiN).

11. The device according to claim 10, wherein titanium silicide is formed in the semiconductor substrate below the first contact plug.

12. A method for fabricating a semiconductor device, comprising:
forming a first dielectric film above a semiconductor substrate;
forming a first opening in the first dielectric film;
causing an aluminum (Al) film to deposit so that the first opening is filled up;
etching an upper part of the Al film filled up in the first opening;
causing a refractory metal material film to deposit inside the first opening formed by the upper part of the Al film being etched; and
forming a wire using copper (Cu) as a material above the refractory metal material film.

13. The method according to claim 12, further comprising: forming a barrier metal film on a wall surface of the first opening before causing the Al film to deposit,
wherein the upper part of the Al film is etched so as to leave the barrier metal film.

14. The method according to claim 13, wherein the barrier metal film contains titanium nitride (TiN).

15. The method according to claim 12, wherein at least one of tungsten (W), tungsten nitride (WN), titanium (Ti), titanium nitride (TiN), tantalum (Ta), tantalum nitride (TaN), and cobalt (Co) is used as a material of the refractory metal material film.

16. The method according to claim 13, further comprising: polishing the refractory metal material film and the barrier metal film sticking out of the first opening before forming the wire after causing the refractory metal material film to deposit.

17. The method according to claim 12, further comprising:
forming a second dielectric film above the first dielectric film and the refractory metal material film before forming the wire; and
forming a second opening reaching the refractory metal material film in the second dielectric film,
wherein the wire is formed in the second opening.

18. The method according to claim 17, further comprising: forming another barrier metal film in the second opening after forming the second opening,
wherein the wire is formed over the refractory metal material film via the other barrier metal film.

19. The method according to claim 12, wherein the wire is formed by being in contact with the refractory metal material film.

20. A method for fabricating a semiconductor device, comprising:
forming a first dielectric film above a semiconductor substrate;
forming a first opening in the first dielectric film;
causing an aluminum (Al) film to deposit so that the first opening is filled up;
etching an upper part of the Al film filled up in the first opening;
causing a refractory metal material film to deposit inside the first opening formed by the upper part of the Al film being etched;
forming a second dielectric film above the first dielectric film and the refractory metal material film;
forming a second opening reaching the refractory metal material film in the second dielectric film;
forming a seed film using copper (Cu) containing manganese (Mn) as a material inside the second opening;
filling the second opening with Cu using the seed film as a cathode electrode; and
forming a barrier film containing Mn, silicon (Si), and oxygen (O) from the seed film.
